(19) United States
(12) Patent Application Publication
(10) Pub. No.: US 2025/0226369 A1
(43) Pub. Date: Jul. 10, 2025

(54) SILICON PHOTONICS CHIP AND METHOD OF MANUFACTURING THE SAME

(71) Applicant: ELECTRONICS AND TELECOMMUNICATIONS RESEARCH INSTITUTE, Daejeon (KR)

(72) Inventors: Sanghwa YOO, Daejeon (KR); Heuk PARK, Daejeon (KR); Joon Ki LEE, Daejeon (KR)

(73) Assignee: ELECTRONICS AND TELECOMMUNICATIONS RESEARCH INSTITUTE, Daejeon (KR)

(21) Appl. No.: 18/954,028

(22) Filed: Nov. 20, 2024

(30) Foreign Application Priority Data
Jan. 10, 2024 (KR) 10-2024-0004441
Mar. 8, 2024 (KR) 10-2024-0033490

(51) Int. Cl. H01L 25/16; H01L 23/00; H01S 5/0234

(52) U.S. Cl. CPC H01L 25/167; H01L 24/16; H01S 5/0234; H01L 2224/10125; H01L 2224/16258; H01L 2924/12042

(57) ABSTRACT

A method of manufacturing a silicon photonics chip may comprise: forming a terrace structure on one surface of a substrate, wherein the terrace structure has a bottom surface of a trench structure formed on the one surface and a plurality of vertical stoppers in a form of a pedestal that protrude integrally with the substrate from the bottom surface, and each of the plurality of vertical stoppers includes a body, an oxide layer formed on an upper surface of the body, and a waveguide layer formed on the oxide layer; forming an under bump metallization (UBM) layer on the bottom surface; forming solder bumps on a light source element; and performing flip-chip bonding of the light source element on which the solder bumps are formed onto the terrace structure so that the solder bumps comes into contact with the UBM layer.

### CROSS-REFERENCE TO RELATED APPLICATIONS

This application claims priority to Korean Patent Applications No. 10-2024-0004441, filed on Jan. 10, 2024, and No. 10-2024-0033490, filed on Mar. 8, 2024, with the Korean Intellectual Property Office (KIPO), the entire contents of which are hereby incorporated by reference.

### BACKGROUND

### 1. Technical Field

Example embodiments of the present disclosure relate to a silicon photonics chip technology, and more specifically, to a multiple-light-source integration structure of a silicon photonics chip and a method of manufacturing the silicon photonics chip.

### 2. Related Art

Silicon photonics technology is a technology in which photonics elements are integrated into a single chip through a manufacturing process for a complementary metal-oxide-semiconductor (CMOS). Using silicon photonics technology, it is possible to mass-produce light sources at low cost, miniaturize the light sources, and increase their capacity.

Silicon photonics technology has the disadvantage in that it is difficult to implement light sources due to the physical properties of silicon. Several methods have been proposed for implementing light sources. As one of the commercializable methods, a method of flip-chip bonding a compound semiconductor-based light source onto a silicon photonics chip is being focused on.

However, in the flip-chip bonding method, it is difficult to align the light sources, and in particular, in a case in which a plurality of light sources are arranged, when the plurality of light sources are sequentially flip-chip bonded, solder bumps formed for the light sources that were previously flip-chip bonded are melted during the flip-chip bonding process of the light sources that are integrated later among the solder bumps formed for the plurality of light sources, causing a problem of optical alignment to be broken.

### SUMMARY

Accordingly, example embodiments of the present disclosure are provided to substantially obviate one or more problems due to limitations and disadvantages of the related art.

Example embodiments of the present disclosure provide a multiple-light-source integration structure of a silicon photonics chip that is capable of efficiently and reliably integrating a plurality of light sources into a silicon photonics chip through optical alignment.

Example embodiments of the present disclosure also provide a method of manufacturing a silicon photonics chip.

According to a first embodiment of the present disclosure, a method of manufacturing a silicon photonics chip may comprise: forming a terrace structure on one surface of a substrate, wherein the terrace structure has a bottom surface of a trench structure formed on the one surface and a plurality of vertical stoppers in a form of a pedestal that protrude integrally with the substrate from the bottom surface, and each of the plurality of vertical stoppers includes a body, an oxide layer formed on an upper surface of the body, and a waveguide layer formed on the oxide layer; forming an under bump metallization (UBM) layer on the bottom surface; forming solder bumps on a light source element; and performing flip-chip bonding of the light source element on which the solder bumps are formed onto the terrace structure so that the solder bumps comes into contact with the UBM layer.

In the forming of the solder bumps, the solder bumps may be formed on an electrode of the light source element.

The electrode may have a metal layer of a form of multilayers including a bonding layer, a diffusion barrier layer, and a wetting layer.

The forming of the solder bumps may include: forming first solder bumps on a first light source element to be flip-chip bonded onto a first terrace structure including a first group of vertical stoppers among the plurality of vertical stoppers; and forming second solder bumps on a second light source element to be flip-chip bonded onto a second terrace structure including a second group of vertical stoppers among the plurality of vertical stoppers.

The performing of the flip-chip bonding may include: performing flip-chip bonding of the first light source element onto the first terrace structure so that the first solder bumps connect an electrode of the first light source element to a first UBM layer.

The performing of the flip-chip bonding may further include: after the performing of the flip-chip bonding of the first light source element, performing flip-chip bonding of the second light source element onto the second terrace structure so that the second solder bumps connect an electrode of the second light source element to a second UBM layer.

At least one of the first light source element and the second light source element may include a 2-port laser diode.

The first group of vertical stoppers and the second group of vertical stoppers may include shared vertical stoppers that are used by both of the first light source element and the second light source element when the flip-chip bonding is performed.

The method may further comprise: filling a gap between the terrace structure and the light source element and filling a gap between the solder bumps with an underfill material.

The method may further comprise: forming at least one edge coupler on the one surface of the substrate through a semiconductor process.

According to a second embodiment of the present disclosure, a silicon photonics chip may comprise: a terrace structure formed on one surface of a substrate in a form of a trench, wherein the terrace structure has a bottom surface formed with a step lowered on the one surface, and a plurality of vertical stoppers in a form of a pedestal that protrude integrally with the substrate from the bottom surface and each of the plurality of vertical stoppers includes a pedestal-shaped body, an oxide layer formed on an upper surface of the body, and a waveguide layer formed on the oxide layer; an under bump metallization (UBM) layer formed on the bottom surface; a light source element flip-chip bonded onto the terrace structure; and solder bumps formed to connect the electrode to the UBM layer through the flip-chip bonding in a state of being formed on the electrode of the light source element in advance.

The electrode may have a form of a multilayer metal layer including a bonding layer, a diffusion barrier layer, and a wetting layer.

The UBM layer may be a single-layer or multi-layer metal layer containing one material or a combination of two or more materials selected from among silver, copper, gold, chromium, aluminum, tungsten, zinc, brass, nickel, iron, bronze, platinum, and tin.

The light source element may include a first light source element flip-chip bonded onto a first terrace structure formed in a first area of the bottom surface, and a second light source element flip-chip bonded onto a second terrace structure formed in a second area of the bottom surface.

The solder bumps may include first solder bumps formed on an electrode of the first light source element that is flip-chip bonded onto the first terrace structure and second solder bumps formed on an electrode of the second light source element that is flip-chip bonded onto the second terrace structure.

Each of the first light source element and the second light source element may be a 2-port light source element including two light sources.

Each of the first light source element and the second light source element may have two 2-port light source elements each including two light sources.

Vertical stoppers positioned in the first area and vertical stoppers positioned in the second area may include shared vertical stoppers used by both of the first light source element and the second light source element.

The silicon photonics chip may further comprise: an underfill material with which a gap between the terrace structure and the light source element and a gap between the solder bumps are filled.

The silicon photonics chip may further comprise: at least one edge coupler formed on the one surface of the substrate.

According to the present disclosure, a multiple terrace structure of a silicon photonics chip is provided for reliably integrating a plurality of light sources into a silicon photonics chip. In a silicon photonics chip having a multiple terrace structure, solder bumps are not formed on the silicon photonics chip in a flip-chip bonding process before a light source such as a LD or the like is placed thereon, and solder bumps are formed on the light source that is flip-chip bonded onto the silicon photonics chip, thereby even when multiple light sources are flip-chip bonded independently or sequentially, enabling very precise optical alignment between the light sources and ECs in the silicon photonics chip.

Further, according to the present disclosure, since light source elements having two or more light sources can be flip-chip bonded onto a silicon photonics chip, it is possible for the present disclosure to effectively supply energy-efficient optical power to an optical transmitter having two or more light source elements.

Further, according to the present disclosure, it is possible for the present disclosure to contribute to the development of optical communication source technology to solve current issues related to data traffic explosion, energy, and construction costs and initiate pioneering of the terabit era.

Further, according to the present disclosure, it is possible to increase capacity of light sources, produce the light sources at low cost, and miniaturize the light sources through the development of a silicon photonics-based single-channel 100 Gbps optical transceiver chip and a 100/400 Gbps optical module. Further, this indicates that the effects of a 4-fold increase in speed per wavelength, a ⅕ decrease in size, and a 40% cost reduction can be achieved.

Further, according to the present disclosure, it is possible for the present disclosure to contribute to the development of a silicon photonics-based board-sized THz signal generator that generates a 300 GHz signal and wirelessly transmits the generated signal at a speed of 100 Gbps.

### BRIEF DESCRIPTION OF DRAWINGS

FIG. 1 is a perspective view for describing a terrace structure of a silicon photonics chip according to one embodiment of the present disclosure.

FIG. 2 is a front view illustrating a structure in which a first light source element is flip-chip bonded onto the silicon photonics chip of FIG. 1.

FIGS. 3A to 3C are a set of exemplary views for describing the flip-chip bonding process of FIG. 2.

FIG. 4 is a schematic perspective view of a multiple terrace structure that can be employed in a multiple-light-source integration structure of a silicon photonics chip according to another embodiment of the present disclosure.

FIGS. 5A to 5D are exemplary diagrams for describing a multiple-light-source integration structure of a silicon photonics chip having the multiple terrace structure of FIG. 4.

FIGS. 6A to 6D are exemplary diagrams for describing a multiple-light-source integration structure of a silicon photonics chip of a comparative example.

FIG. 7 is a schematic plan view for describing a silicon photonics-based optical transmitter in which the multiple-light-source integration structure using the multiple terrace structure of FIG. 4 is employed.

FIG. 8 is a schematic perspective view of a multiple terrace structure that can be employed in a multiple-light-source integration structure of a silicon photonics chip according to still another embodiment of the present disclosure.

FIGS. 9A and 9B are exemplary diagrams for describing a process for manufacturing a multiple-light-source integration structure of a silicon photonics chip having the multiple terrace structure of FIG. 8.

FIG. 10 is a graph showing a relationship between injection current and optical power for a silicon photonics chip with a light source element integrated on the multiple terrace structure of FIG. 8.

FIG. 11 is an exemplary diagram for describing a light source element that can be employed in the multiple-light-source integration structure of the silicon photonics chip of the present embodiment.

FIG. 12 is a schematic plan view for describing a silicon photonics-based optical transmitter to which a multiple-light-source integration structure according to still another embodiment of the present disclosure is employed.

FIGS. 13A to 13D are exemplary diagrams for describing a flip-chip bonding process that can be employed in the multiple-light-source integration structure of the silicon photonics chip of FIG. 12.

FIG. 14 is a schematic plan view of a control device of semiconductor equipment that performs a method of manufacturing a silicon photonics chip according to the present embodiment.

FIG. 15 is an exemplary diagram illustrating a light source integration structure of a silicon photonics chip in a comparative example.

FIG. 16 is another exemplary diagram illustrating a light source integration structure of a silicon photonics chip in another comparative example.

### DETAILED DESCRIPTION OF THE EMBODIMENTS

While the present disclosure is capable of various modifications and alternative forms, specific embodiments thereof are shown by way of example in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the present disclosure. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

In exemplary embodiments of the present disclosure, “at least one of A and B” may refer to “at least one A or B” or “at least one of one or more combinations of A and B”. In addition, “one or more of A and B” may refer to “one or more of A or B” or “one or more of one or more combinations of A and B”.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present disclosure will be described in greater detail with reference to the accompanying drawings. In order to facilitate general understanding in describing the present disclosure, the same components in the drawings are denoted with the same reference signs, and repeated description thereof will be omitted.

Prior to describing the present embodiments, two comparative examples will be described below to aid in understanding the present disclosure.

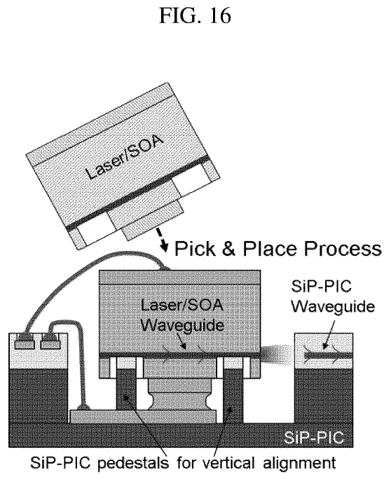

As shown in FIGS. 15 and 16, comparative examples show structures in which a laser diode (LD), which is a light source, is integrated into a silicon photonics chip by flip-chip bonding. Comparative Example 1 of FIG. 15 is a representative diagram described in “Optically Aligned Hybrid Semiconductor Device and Method” of United States (US) Unexamined Patent Application Publication No. 2016/029165 A1. Comparative Example 2 of FIG. 16 is a schematic diagram of a flip-chip bonding concept of the paper “Hybrid Silicon Photonics Flip-Chip Laser Integration with Vertical Self-Alignment” published at the Conference on Lasers and Electro-Optics Pacific Rim, CLEO-PR 2017 s2069.

Specifically, in Comparative Example 1, a terrace is formed on one surface of a silicon substrate 101 and an under bump metallization (UBM) layer 181 and ball-shaped solder bumps 188 are provided. UBM may also be referred to as an under bump metallurgy. Further, in Comparative Example 1, a method of forming a first alignment surface 151 serving as a stopper for aligning a height of an optical mode of an optical waveguide (WG) 221 of a LD 222 and a height of an optical mode of a silicon photonics chip and a second vertical alignment surface 152 for an optical mode of a light source by utilizing a SiO₂ BOX (buried oxide) layer or a silicon substrate layer is proposed.

Meanwhile, the flip-chip bonding method of Comparative Example 1 has a problem in that it is difficult to implement an accurate height because there is no separate boundary inside an LD tip when an upper silicon dioxide layer is partially removed to form the second vertical alignment surface 152 during the light source integration process. Further, there may be a problem in that it is difficult to implement an accurate height even at a height below that, which increases time and cost. In addition, since the solder bumps 188 are formed on the UBM layer 181 of the silicon photonics chip, performing independent flip-chip bonding may be difficult when attempting to integrate a plurality of light sources. That is, when multiple light sources are sequentially flip-chip bonded, the solder bumps of the light source that are previously flip-chip bonded may melt when flip-chip bonding is performed on a specific light source, causing a serious problem of optical alignment to be broken.

In addition, Comparative Example 2 shows a structure in which a light source equipped with a laser/semiconductor optical amplifier (SOA) is integrated by flip-chip bonding into a silicon photonics chip equipped with system-in-package photonic integrated circuit (SiP-PIC) pedestals as stoppers for vertical alignment through a pick & place process. In Comparative Example 2, an upper surface of a stopper is formed to have a very precise height using a silicon waveguide (Si WG) layer, which is a 220 nm thick silicon element layer. This is because a boundary between the silicon element layer and a silicon oxide (SiO₂) film can be precisely etched.

Meanwhile, in Comparative Example 2, when a silicon element layer is implemented as a stopper, a light source should be designed and manufactured so that the center of an optical mode of the light source can be aligned with a center of height of an optical mode of the silicon element layer. However, in Comparative Example 2, in a similar manner to the case of Comparative Example 1, since solder bumps are formed on an UBM layer of a silicon photonics chip, it may be difficult to independently perform flip-chip bonding when attempting to sequentially integrate a plurality of light sources. That is, when multiple light sources are sequentially flip-chip bonded, the solder bumps that are previously flip-chip bonded may melt when the solder bumps are flip-chip bonded subsequently, causing a problem of optical alignment to be broken after integration.

In order to solve the problems caused in the comparative examples described above, in a multiple-light-source integration structure of a silicon photonics chip in the present embodiment, a multiple terrace structure of a silicon photonics chip in which solder bumps for flip-chip bonding are not formed and a structure of a light source element in which solder bumps for flip-chip bonding are formed are used.

That is, in the multiple-light-source integration structure of the silicon photonics chip in the present embodiment, when a plurality of light sources are sequentially integrated into a silicon photonics chip, each light source may be optically aligned very precisely even when multiple light source elements are independently and sequentially flip-chip bonded. In addition, the multiple-light-source integration structure of the silicon photonics chip in the present embodiment may be effectively applied to a method of flip-chip bonding light source elements each equipped with at least two light sources in order to supply energy-efficient optical power.

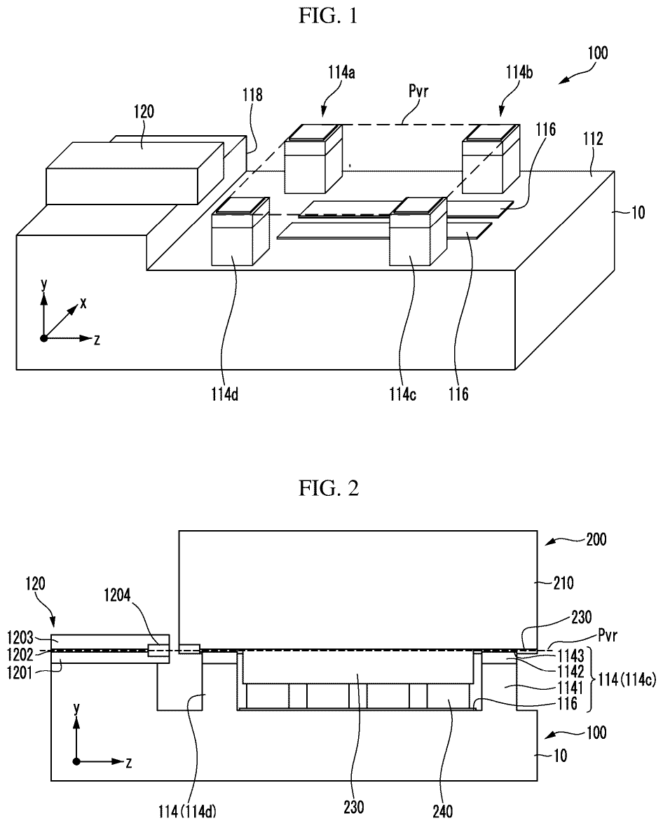

FIG. 1 is a perspective view for describing a terrace structure of a silicon photonics chip according to one embodiment of the present disclosure. In addition, FIG. 2 is a front view illustrating a structure in which a first light source element is flip-chip bonded onto the silicon photonics chip of FIG. 1.

Referring to FIGS. 1 and 2, a silicon photonics chip 100 includes a silicon substrate 10 having a terrace structure. Further, the silicon photonics chip 100 may include an edge coupler (EC) 120 provided on one surface or upper surface of the silicon substrate 10.

The terrace structure may include a bottom surface 112, vertical stoppers 114a, 114b, 114c, and 114d formed on the bottom surface 112, and one pair of UBM layers 116 formed between the vertical stoppers.

The bottom surface 112 has a step 118 with respect to the upper surface of the silicon substrate 10 and may be formed to be closer to the other surface, which is an opposite surface of the one surface of the silicon substrate 10, than to the upper surface.

The vertical stoppers 114a, 114b, 114c, and 114d may be arranged at regular intervals on the bottom surface 112 and have a shape like four pillars. Each of the vertical stoppers 114a, 114b, 114c, and 114d (hereinafter simply 114) may include a lower body 1141 formed integrally with the silicon substrate 10, an oxide layer 1142 that is formed on the lower body 1141 and made of silicon oxide (SiO₂), and a silicon element layer 1143 formed on the oxide layer 1142. The lower body 1141 may be referred to as a vertical stopper body or simply a body, and the silicon element layer 1143 may be referred to as a WG layer made of a silicon material.

The four vertical stoppers 114a, 114b, 114c, and 114d may form a virtual plane in which upper surfaces of the four vertical stoppers 114a, 114b, 114c, and 114d correspond to corners of a quadrangle. The virtual plane may function as a vertical reference plane with respect to a height from the bottom surface when the light source element is flip-chip bonded onto the terrace structure. In particular, the silicon element layer 1143 not only may function as a layer that precisely forms the heights of the vertical stoppers 114a, 114b, 114c, and 114d when a multiple trench structure is formed, but may also function to reliably form optical alignment with a WG layer or spot size converter (SSC) of a light source element 200 (see FIG. 2) to be flip-chip bonded subsequently and an SSC or WG layer of the EC 120. Here, the SSC or WG layer of the EC 120 may be a component implemented integrally into a silicon photonics chip using a complementary metal-oxide semiconductor (CMOS) process or a process compatible with the CMOS process.

The one pair of UBM layers 116 may be formed in the form of two-line stripes or a pair of thin films between the four vertical stoppers 114a, 114b, 114c, and 114d. Naturally, the UBM layers 116 may be formed in an arbitrary shape to include a stripe section and extend along an arbitrary path to a component that requires electrical connection as an electrode layer.

Each UBM layer 116 is a typical multilayer metal layer formed between an electrode and a bump to facilitate adhesion onto an aluminum (Al) or copper (Cu) electrode of a semiconductor chip and prevent diffusion into the chip and may be formed in a three-layer structure of a bonding layer, a diffusion prevention layer, and a wettable layer. Meanwhile, in the present embodiment, since the light source element is configured to be flip-chip bonded in a state in which solder bumps 240 (see in FIG. 2) in the form of a ball, pillar, or a paste are formed on the electrode of the die of the light source element on which the light source element is mounted, and solder bumps are not formed on the silicon substrate on which the UBM layers 116 are formed, a single-layer or multi-layer metal layer may be used as the UBM layer 116 of the present embodiment.

That is, the UBM layer 116 may be formed as a single-layer or multi-layer metal layer containing one material or a combination of two or more materials selected from among silver, copper, gold, chromium, aluminum, tungsten, zinc, brass, nickel, iron, bronze, platinum, and tin as a main component.

The EC 120 may include a WG layer 1202 made of a silicon material as an optical WG. The WG layer 1202 may be provided between a lower oxide layer 1201 and an upper oxide layer 1203 forming the EC 120 and be referred to as a second WG layer. The second WG layer 1202 may be formed as a thin layer formed of silicon and be referred to as a silicon element layer. In addition, the above-described upper oxide layer 1203 may be referred to as an upper clad layer.

Further, the EC 120 may be optionally provided with an SSC 1204 for effective optical coupling on a light incident side of the second WG layer 1202. The SSC 1204 may have a tapered shape or an inverse tapered shape, which is an opposite shape of the tapered shape. The light source element 200 may be flip-chip bonded onto the silicon photonics chip 100 having the terrace structure described above. The light source element 200 may include a die 210, a WG layer 220, and an electrode 230. The die 210 may refer to a piece of semiconductor material. The WG layer 220 may be formed on one surface or lower surface of the die 210. The above-described WG layer 220 may be referred to as a first WG layer and have an SSC in a light output portion. In addition, the electrode 230 may be formed on one surface of the die 210 outside an area in which the first WG layer 220 is formed.

When the light source element 200 is integrated onto the silicon photonics chip 100 such as a SiP chip through flip-chip bonding, the solder bumps 240 formed on the light source element 200 may be arranged between the vertical stoppers 114a, 114b, 114c, and 114d in the form of pedestals forming the etched trench structure in the silicon substrate 10 to come into contact with the UBM layer 116 formed on the silicon substrate 10.

In this case, the light-source integration structure of the silicon photonics chip may function to ensure that the first WG layer 220 and the second WG layer 1202 are well aligned on an optical path of the light source element 200. The first WG layer 220 may be expressed as an optical mode of the silicon photonics chip 100, and the second WG layer 1202 may be expressed as an optical mode of the light source element 200.

The above-described light source element 200 may include at least any one light source selected from among a LD, a light emitting diode (LED), and an SOA as an on-chip light source. A light source element equipped with one light source or optical element may be simply referred to as a light source or optical element.

According to the above-described configuration, the light source element 200 may be stably mounted at a height supported by the vertical stoppers 114a, 114b, 114c, and 114d, and thereby, the first WG layer 220 of the light source element and the second WG layer 1202 of the EC 120 may be optically aligned effectively along a vertical reference plane formed on uppermost portions of the vertical stoppers 114a, 114b, 114c, and 114d.

In the present embodiment, the flip-chip bonded area of the light source element corresponds to a position at which the silicon substrate 10 is partially etched to have a terrace structure. In order to align the center of height of the optical mode of the flip-chip light source element 200, the vertical stoppers 114a, 114b, 114c, and 114d are provided in the terrace structure. In addition, the upper surface of each vertical stopper is formed with the silicon element layer 1143. Here, a thickness of the silicon element layer 1143 is typically 220 nm. When the light source element 200 is flip-chip bonded, on the basis of the silicon element layer 1143, the center of height of the first WG layer 220 of the light source element 200 may be reliably aligned with the center of height of the optical mode of the EC 120 having the second WG layer 1202 composed of the Si WG layer. The silicon element layer 1143 and the second WG layer 1202, which are WG layers, may be formed as the same layer in the process of manufacturing the semiconductor.

The advantages of the light-source integration structure of the silicon photonics chip of the present embodiment described above are summarized as follows.

First, since the silicon element layer is used for the upper surfaces of the vertical stoppers, the height of each vertical stopper may be precisely adjusted in units of tens of nanometers using a semiconductor process.

Second, since the silicon photonics chip and the height of the optical mode of the light source element are automatically aligned through the vertical stoppers, a complexity of flip-chip bonding may be significantly reduced.

Third, when the light source element is flip-chip bonded, the solder bumps are not formed on the silicon photonics chip but are formed only on the light source element, and thus it is possible to prevent optical alignment from being broken when multiple light source elements are independently flip-chip bonded onto a multiple terrace structure.

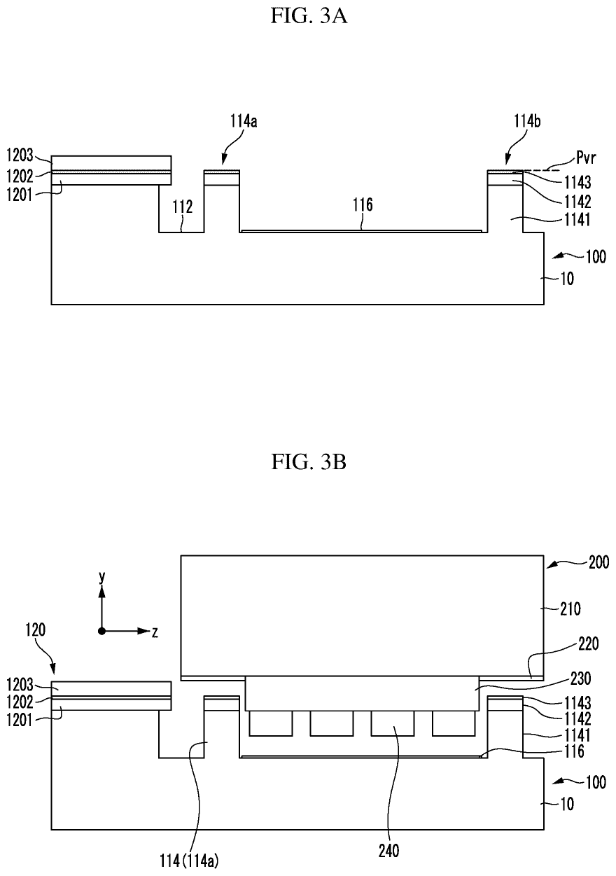

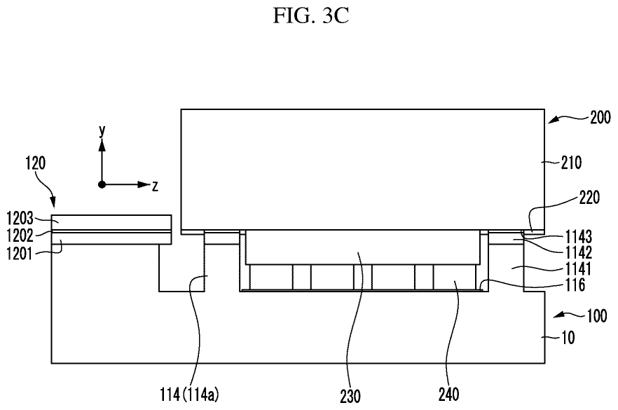

FIG. 3A to FIG. 3C are a set of exemplary views for describing the flip-chip bonding process of FIG. 2.

Referring to FIG. 3A, a silicon photonics chip in which a trench structure is formed by partially etching one surface of a silicon substrate 10 may be prepared. A light source element is not yet flip-chip bonded onto the silicon photonics chip.

The trench structure may include a bottom surface 112 positioned to be closer to the other surface than one surface of the silicon substrate 10, and a plurality of vertical stoppers 114a and 114b that are arranged at regular intervals on the bottom surface 112 and formed integrally with the silicon substrate 10. Further, an EC 120 (see FIG. 3B) may be provided together on one surface of the silicon substrate 10.

An example of the process for forming the plurality of vertical stoppers and the EC is briefly described as follows. In this case, the above-described formation process may be performed by a control device that controls the operation of semiconductor equipment and semiconductor devices.

First, a silicon substrate 10 having one surface on which a first layer, a second layer, and a third layer are stacked to form a terrace structure may be prepared. The first layer may include a first oxide layer 1142 and a lower oxide layer 1201. These oxide layers 1201 and 1142 may be silicon oxide layers. The second layer may include a WG layer 1202 and a silicon element layer 1143. In addition, the third layer may include an upper oxide layer 1203 and be referred to as an upper class layer.

Next, in order to form vertical stoppers, the upper oxide layer 1203, which is the third layer on the one surface of the silicon substrate 10, may be etched to expose the WG layer 1202 and the silicon element layer 1143 that are formed in the same layer.

Next, the lower oxide layer 1201 and the silicon substrate 10 may be partially etched to form each of vertical stoppers 114a and 114b. Here, the silicon substrate 10 may be etched as much as several micrometers. Further, a portion of one surface of the silicon substrate 10 may be additionally etched by about several tens of micrometers to the bottom surface 112 to form an SSC of the EC 120.

In actuality, the bottom surface 112 on which a UBM layer 116 is formed and a portion of a bottom portion on which the SSC is formed are expressed identically, but the present disclosure is not limited to such a configuration, and an etching depth of the portion of the bottom surface on which the SSC is formed may be set differently from an etching depth of the bottom surface 112 on which the UBM layer 116 is formed. For example, the etching depth of the portion of the bottom surface on which the SSC is formed may be formed to be greater than the etching depth of the bottom surface 112 on which the UBM layer 116 is formed.

Next, the UBM layer 116 extending between bodies 1141 of the vertical stoppers may be formed on the bottom surface 112.

According to the above-described configuration, each of the vertical stoppers 114a and 114b may be formed in the form of a pedestal having a structure in which the body 1141, the first oxide layer 1142, and the silicon element layer 1143 are stacked. A virtual plane formed by connecting uppermost surfaces of the vertical stoppers 114a and 114b may function as a vertical reference plane Pvr in flip-chip bonding of the light source element. In addition, the EC 120 may be formed in a structure in which the lower oxide layer 1201, the WG layer 1202, and the upper oxide layer 1203 are stacked.

As described above, as illustrated in FIG. 3B, when a silicon photonics chip having a trench structure is prepared, ball-shaped solder bumps 240 may be formed on an electrode 230 of a light source element 200. That is, the solder bumps 240 may be bumper-bonded onto a rear surface of the light source element.

Thereafter, as illustrated in FIG. 3C, the light source element 200 may be flip-chip bonded onto a silicon photonics chip 100 so that the WG layer 220 of the light source element 200 is aligned with the vertical reference plane Pvr while the solder bumps 240 come into contact with the UBM layer 116 formed between the vertical stoppers 114a and 114b.

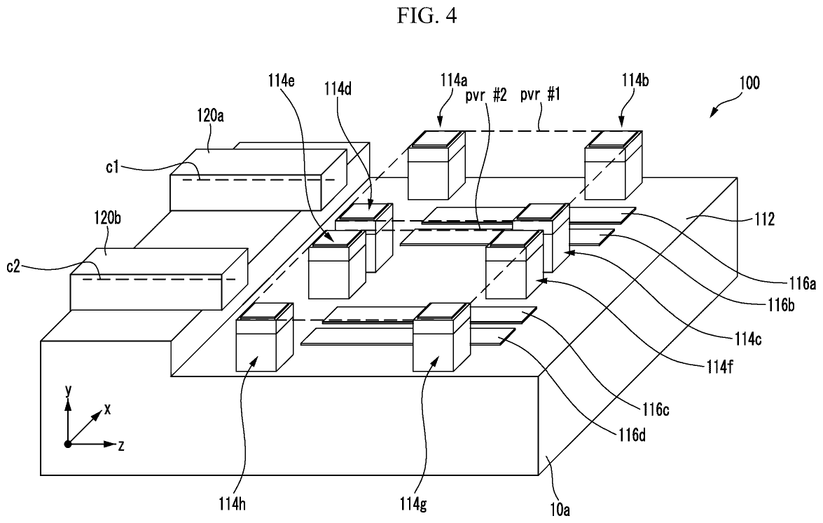

FIG. 4 is a schematic perspective view of a multiple terrace structure that can be employed in a multiple-light-source integration structure of a silicon photonics chip according to another embodiment of the present disclosure.

Referring to FIG. 4, a silicon photonics chip 100 may include a silicon substrate 10 having a trench structure, and include a first EC 120a and a second EC 120b that are installed on one surface or upper surface of the silicon substrate 10. That is, the silicon photonics chip 100 of the present embodiment may have a multiple terrace structure capable of integrating two or more light source chips through flip-chip bonding.

The multiple terrace structure may include a bottom surface 112, a first group of vertical stoppers 114a, 114b, 114c, and 114d and a second group of vertical stoppers 114e, 114f, 114g, and 114h that are formed on the bottom surface 112, one pair of first UBM layers 116a and 116b formed between the first group of vertical stoppers, and one pair of second UBM layers 116c and 116d formed between the second group of vertical stoppers.

An oxide layer and a silicon element layer may be provided on an upper surface of each of the first and second groups of vertical stoppers. An uppermost surface of the first group of vertical stoppers, each of which has a silicon element layer, may form a first vertical reference plane Pvr #1 for a first light source element, and an uppermost surface of the second group of vertical stoppers, each of which has another silicon element layer, may form a second vertical reference plane Pvr #2 for a second light source element. Here, when the first and second light source elements are flip-chip bonded, a first WG layer of each of the light source elements may be optically aligned (c1, c2) with a second WG layer of each of the ECs 120a and 120b.

In addition, since detailed descriptions of the configuration and function of each vertical stopper and each UBM are substantially the same as detailed descriptions of those of the corresponding components in FIGS. 1 to 3B, the descriptions thereof will be omitted to avoid repetition of description.

In this way, the multiple terrace structure that can be employed in the multiple-light-source integration structure of the present embodiment may be formed so that multiple light source elements can be flip-chip bonded simultaneously or sequentially. Such a multiple terrace structure is not limited to two light source elements being flip-chip bonded as in the example of the present embodiment and may be configured so that three or more light source elements are flip-chip bonded. The flip-chip bonding of each light source element may be referred to in the drawing illustrated in FIG. 3B.

According to the configuration of the present embodiment, heights of optical modes of the flip-chip bonded light source elements and ECs 120a and 120b may be automatically aligned, thereby allowing output light of the light source elements to be transmitted to silicon optical WGs of the ECs 120a and 120b and properly transmitted to another light source. Here, each of the ECs 120a and 120b may include an SSC for effective optical coupling. A thickness of the SSC of each of the ECs 120a and 120b may be about 6 μm.

One main feature of the present disclosure is that solder bumps are formed on electrodes of the light source elements instead of forming solder bumps on UBM layers of the silicon photonics chip and then flip-chip bonding is performed. For example, in the multiple-light-source integration structure of the present embodiment, for wavelength multiplexing or wavelength division multiplexing (WDM) of the silicon photonics chip, a light source element (a first light source element) of a L1 wavelength may be flip-chip bonded onto a first terrace structure (hereinafter, simply referred to as a “first terrace”) of the multiple terrace structure, and a light source element (a second light source element) of a L2 wavelength may be flip-chip bonded onto a second terrace structure (hereinafter, simply referred to as a “second terrace”) of the multiple terrace structure.

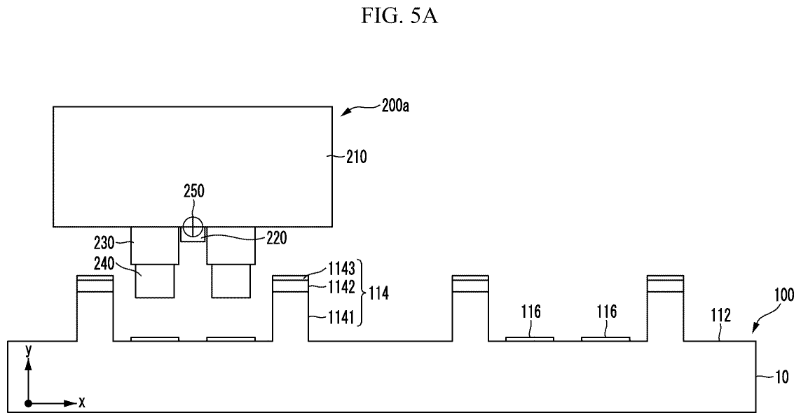

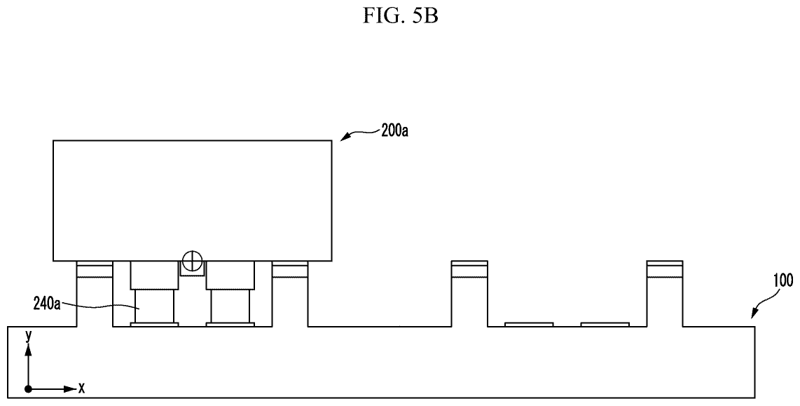

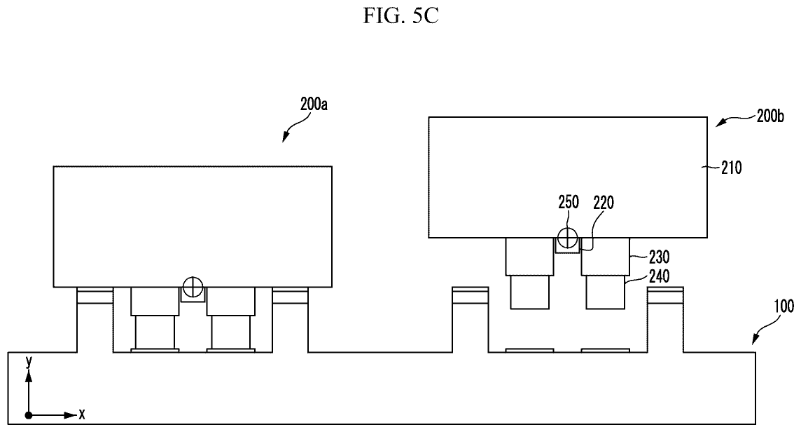

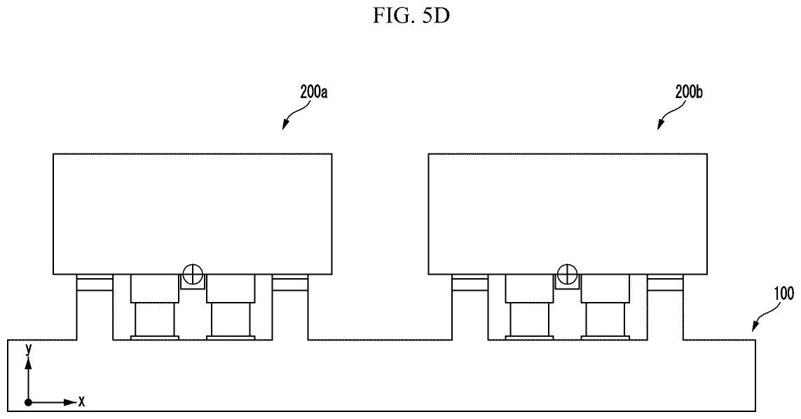

FIGS. 5A to 5D are exemplary diagrams for describing a multiple-light-source integration structure of a silicon photonics chip having the multiple terrace structure of FIG. 4. Referring to FIGS. 5A to 5D, a silicon photonics chip 100, a first light source element 200a, and a second light source element 200b may be prepared. The first light source element 200a and the second light source element 200b may have different wavelengths and be placed in different areas of the silicon photonics chip 100, but their configurations and functions may be substantially the same.

The silicon photonics chip 100 may include a silicon substrate 10, a plurality of vertical stoppers 114, and at least one pair of UBM layers 116 arranged between the plurality of vertical stoppers. The silicon photonics chip 100 may include at least two terrace structures. In this case, for example, a first group of vertical stoppers may be arranged on a first terrace, and a second group of vertical stoppers may be arranged on a second terrace.

Here, each vertical stopper 114 may include a body 1141 formed in the form of a pillar or pedestal that integrally protrudes from a bottom surface 112 of the terrace and an oxide layer 1142 and a silicon element layer 1143 that are formed on an upper surface of the body 1141. The oxide layer 1142 may be an oxide silicon layer, and the silicon element layer 1143 may be a WG layer made of a silicon material.

No solder bumps are formed on the silicon photonics chip 100 illustrated in FIG. 5A. The silicon photonics chip 100 is prepared for flip-chip bonding of light source elements.

The first light source element 200a may include a die 210, a WG layer 220, an electrode 230, and a light source 250. Further, in a similar manner to the first light source element 200a, the second light source element 200b may include a die, a WG layer, an electrode, and a light source (see FIG. 5C).

Meanwhile, when the first light source element 200a is flip-chip bonded onto the silicon photonics chip 100, solder bumps 240 may be formed on the electrode 230 of the first light source element 200a. As illustrated in FIG. 5B, he first light source element 200a on which the solder bumps are formed may be flip-chip bonded onto the silicon photonics chip 100.

Next, as illustrated in FIG. 5C, in order for the second light source element 200b to be flip-chip bonded onto the silicon photonics chip 100, the solder bumps 240 may be formed on the electrode 230 of the second light source element 200b.

The process for forming the solder bumps on the light source element itself may follow the existing flip-chip bump formation process. For example, a seed layer may be formed by a sputtering process on a circuit board (in the present embodiment, the electrode of the light source element) on which an input/output (I/O) final metal pad is exposed between an insulating layer or a dielectric layer, a photoresist may be applied and patterned on the seed layer, and then a solder bump may be formed by electroplating. In this case, in a case of a copper post bump or copper pillar bump (CPB), copper (Cu) may be plated on a metal pad of a chip on which a photoresist is patterned to form a post, and a solder bump may be formed on the post. As the solder bump, Sn—Ag, which is a lead-free solder bump, may be used.

According to the configuration of the present embodiment, as illustrated in FIG. 5D, at least one first light source element 200a may be flip-chip bonded onto a first area on the silicon photonics chip 100 and then the second light source element 200b may be flip-chip bonded onto a second area on the silicon photonics chip 100, and by this configuration, the problem of solder bumps melting down and causing optical alignment errors may be solved.

In other words, when a first light source element 200a of a first wavelength is flip-chip bonded onto the multiple terrace structure of the silicon photonics chip 100, only UBM layers are formed without solder bumps in the multiple terrace structure, and solder bumps 240 are formed on the electrode 230 of the light source element (see FIG. 5A). When the first light source element 200a is flip-chip bonded onto the multiple terrace structure, the solder bumps 240 react with the UBM layers 116 of the first terrace, thereby changing a melting point. That is, the solder bumps may be formed using an Au—Sn material, and the UBM layer may be formed using a gold (Au) material. In this case, solder bumps 240a flip-chip bonded onto the UBM layers may have a different composition ratio, resulting in an increase in the melting point (see FIG. 5B). Such solder bumps 240a may be referred to as solder after heating (SAH). Thereafter, even when a second light source element 200b of a second wavelength is flip-chip bonded at the same temperature in the flip-chip process, the second light source element 200b may be flip-chip bonded without affecting the first light source element 200a (see FIGS. 5C and 5D). This is because the melting point of the solder bumps 240a of the first light source element 200a rises to be higher than the melting point of the solder bumps 240 of the second light source element 200b prior to the flip-chip bonding.

The solder bump described above may have a size of several micrometers (μm) to several hundred μm, and the material of the solder bump may include any one of gold (Au), chromium (Cr), aluminum (Al), and tin (Sn) or a combination thereof.

In this way, in the present embodiment, by utilizing the properties according to the bonding relationship between the solder bumps used for flip-chip bonding and the UBM layers, multiple light source elements may be effectively flip-chip bonded onto the multiple terrace structure of the silicon photonics chip.

After all of a plurality of light source elements are flip-chip bonded onto a multiple terrace structure, a manufacturing device may fill a gap between the solder bumps, which are flip-chip bumps, with a polymer-based underfill material, to ensure the reliability of the solder bump joints. Naturally, depending on the implementation, the multiple-light-source integration structure of the present embodiment may be configured to perform flip-chip bonding after applying a fluxing underfill and then performing a reflow process.

Further, when the light source is flip-chip bonded onto the terrace structure, the manufacturing device may be configured to coat the solder bumps on the light source with a polymer material including metal powder and then perform flip-chip bonding. The metal powder may be composed of particles having a diameter of 1 nanometer (nm) to 1 micrometer (μm) and may have a characteristic of melting at an underfill resin curing temperature of 100° C. or higher. The metal powder may be composed of any one of bismuth (Bi), aluminum (Al), copper (Cu), lead (Pb), and nickel (Ni) or a combination thereof. In addition, the polymer material may be composed of any one of nitrogen-containing polymers, polylysine, polyethyleneimine, poly(diallyl dimethyl ammonium chloride), poly(allylamine hydrochloride), carboxylic acid groups, sulfonic acid groups, nitric acid groups, and phosphoric acid groups or a combination thereof.

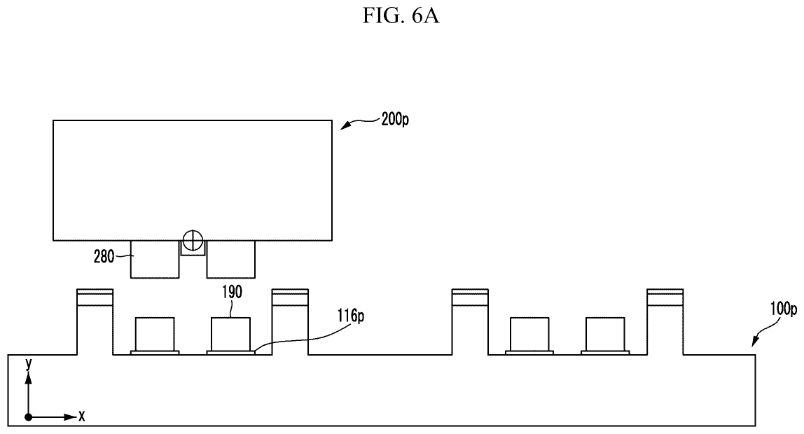

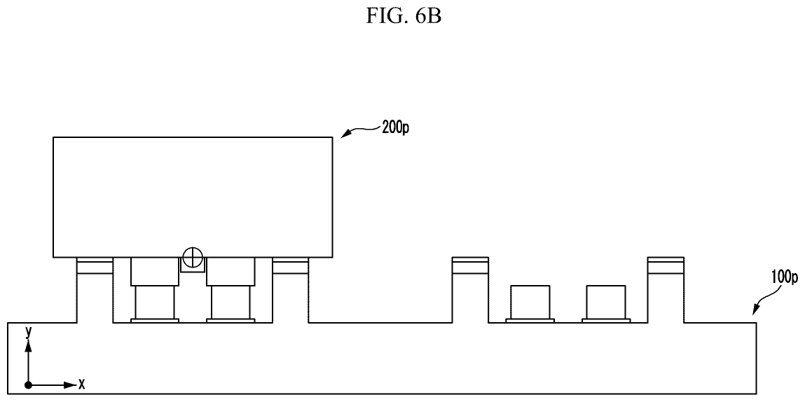

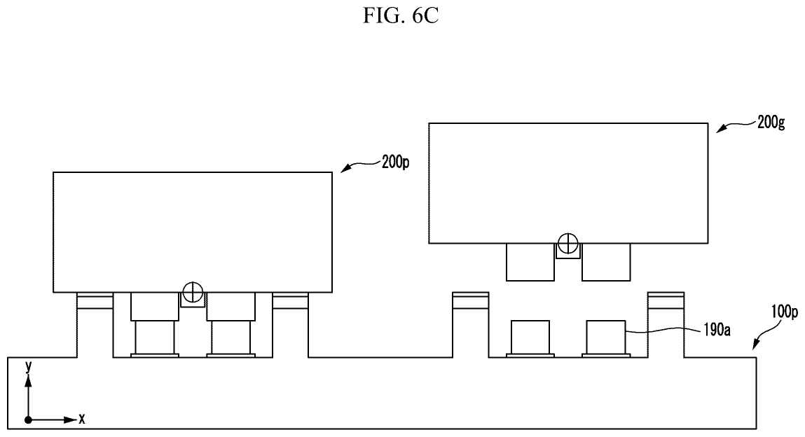

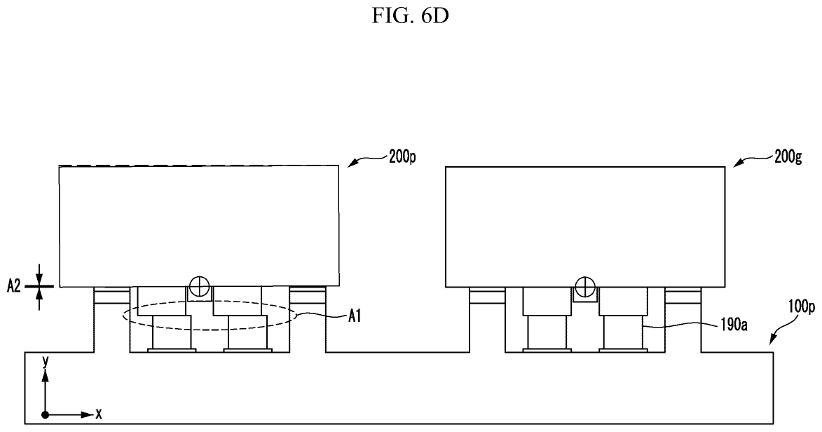

FIGS. 6A to 6D are exemplary diagrams for describing a multiple-light-source integration structure of a silicon photonics chip of a comparative example.

Referring to FIGS. 6A to 6D, in the comparative example, when a first light source element 200p and a second light source element 200q are flip-chip bonded onto a silicon photonics chip 100p, solder bumps 190 are formed on a plurality of UBM layers positioned on a terrace of the silicon photonics chip 100p.

In the case of the comparative example, when a first light source element 200p of a L1 wavelength is flip-chip bonded, the property of all surrounding solder bumps 190 is changed, and thus a temperature condition for flip-chip bonding a second light source element 200q of a L2 wavelength should be changed. For example, in a case in which solder bumps 190 made of an Au—Sn material and UBM layers 116p made of an Au material are used, when the first light source element 200p is flip-chip bonded, a melting point of solder bumps 190a in contact with the UBM layers 116p is increased, and thus the temperature for flip-chip bonding the second light source element 200q should be increased. In addition, when the second light source element 200q is flip-chip bonded at a high temperature, the solder bumps of the first light source element 200p that has been previously flip-chip bonded may melt again, thereby causing alignment errors A1 and A2, and thus causing a serious problem in optical alignment.

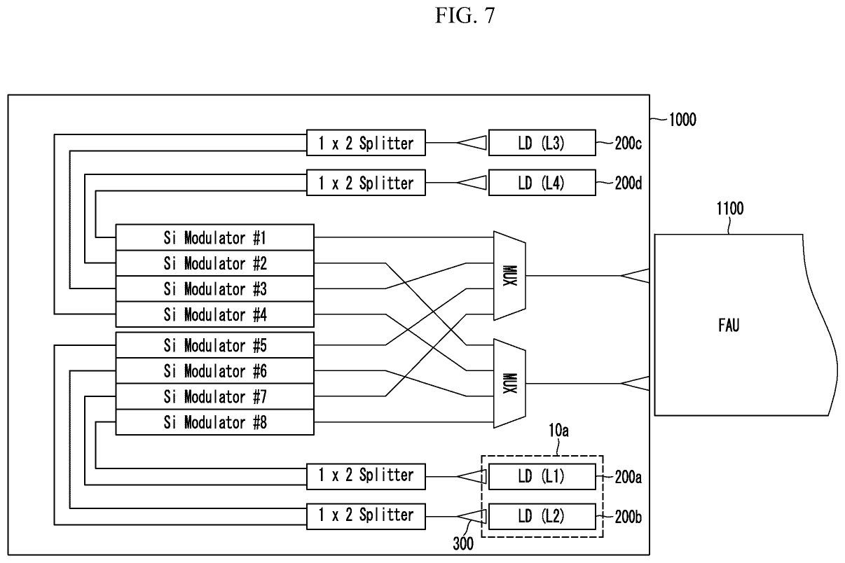

FIG. 7 is a schematic plan view for describing a silicon photonics-based optical transmitter in which the multiple-light-source integration structure using the multiple terrace structure of FIG. 4 is employed.

The multiple-light-source integration structure of the silicon photonics chip having the multiple terrace structure of the present embodiment supports a method of forming solder bumps on a light source element and independently flip-chip bonding multiple light source elements onto the multiple terrace structure. That is, in manufacturing the silicon photonics-based optical transmitter of the present embodiment, a configuration may be included in which solder bumps are formed on a light source element without forming solder bumps on UBM layers of a terrace structure, thereby performing flip-chip bonding on the light source element.

As illustrated in FIG. 7, the multiple-light-source integration structure of the silicon photonics chip may be configured based on silicon photonics, in which two light sources elements 200a and 200b for coarse wavelength division multiplexing (CWDM) optical transmission are each flip-chip bonded onto a single silicon substrate 10a. In such a silicon photonics-based optical transceiver, the silicon photonics chip may be referred to as a silicon photonics 2×CWDM optical transmission chip.

An output of each of four light source elements flip-chip bonded onto the silicon photonics chip may be coupled to a silicon optical WG through an EC 300, which is an optical coupling device. The EC 300 may correspond to any one of the ECs 120, 120a, and 120b (see FIGS. 3B and 4) of the above-described embodiments. The output of each light source element may be split into two pieces through a 1×2 optical splitter, modulated through a silicon optical modulator (Si modulator), wavelength-multiplexed in a multiplexer (MUX), and then output to a fiber array unit (FAU) 1100.

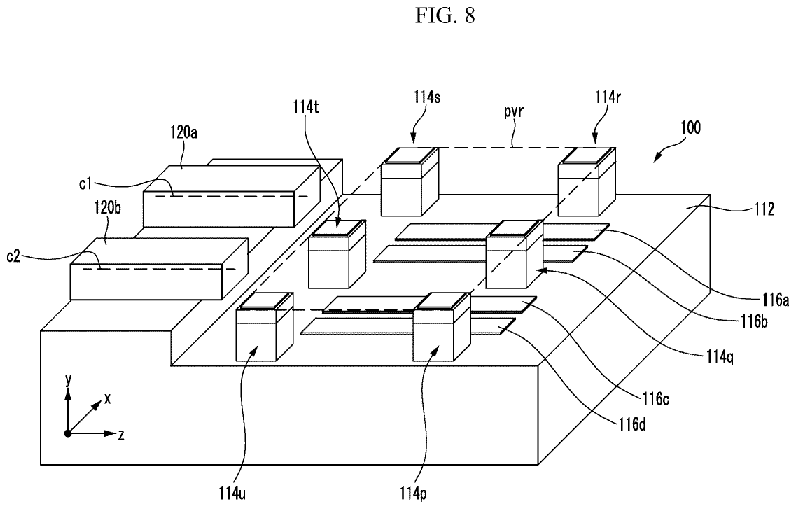

FIG. 8 is a schematic perspective view of a multiple terrace structure that can be employed in a multiple-light-source integration structure of a silicon photonics chip according to still another embodiment of the present disclosure.

The multiple terrace structure of the present embodiment may be applied to a silicon photonics chip in which a 2-Port-LD (2P-LD), in which two LDs which are light source elements are manufactured together on a single die, is integrated by flip-chip bonding. In particular, as compared to the multiple terrace of FIG. 4, the multiple terrace structure of the present embodiment has a form in which the number of vertical stoppers is reduced due to sharing vertical stoppers positioned adjacent to each other on the first terrace and the second terrace.

Recently, in related art, high output/optical power light source elements are required due to the insertion loss of a silicon light source in a silicon PIC, and the above-described demand may be met through the manufacturing method in which the multiple terrace structure and the solder bumps are formed on each of the plurality of light source elements of the present embodiment and the multiple terrace structure and the solder bumps are flip-chip bonded.

Specifically, a silicon photonics chip 100 may include a silicon substrate 10 having a multiple terrace structure for flip-chip bonding two or more light source elements and include a first EC 120a and a second EC 120b that are installed on one surface or upper surface of the silicon substrate 10.

The multiple terrace structure may include a bottom surface 112, a first group of vertical stoppers 114q, 114r, 114s, and 114t and a second group of vertical stoppers 114p, 114q, 114t, and 114u that are formed on the bottom surface 112, one pair of first UBM layers 116a and 116b formed between the first group of vertical stoppers, and one pair of second UBM layers 116c and 116d formed between the second group of vertical stoppers. Here, the two vertical stoppers 114q and 114t belong in common to the first group and the second group. That is, the two vertical stoppers 114q and 114t are shared by the first group and the second group.

An oxide layer and a silicon element layer may be provided on an upper surface of each of the first and second groups of vertical stoppers. An uppermost surface of the first group of vertical stoppers, each of which has a silicon element layer, may form a first vertical reference plane for the first light source element, and an uppermost surface of the second group of vertical stoppers, each of which has another silicon element layer, may form a second vertical reference plane for the second light source element. In addition, the first vertical reference plane and the second vertical reference plane may form one vertical reference plane Pvr. Thereafter, when each of the first light source element and the second light source element is flip-chip bonded, a first WG layer of each light source element may be optically aligned (c1, c2) with a second WG layer of each of the ECs 120a and 120b.

Since detailed descriptions of the configuration and function of each vertical stopper described above and each UBM layer are substantially the same as detailed descriptions of those of the corresponding components in FIGS. 1 to 4, the descriptions thereof will be omitted to avoid repetition of description.

In this way, the multiple terrace structure of the silicon photonics chip that can be employed in the multiple-light-source integration structure of the present embodiment may be formed so that multiple light sources can be flip-chip bonded simultaneously or sequentially. In particular, when a plurality of light sources are flip-chip bonded, the multiple terrace structure may allow adjacent light sources to share and use the vertical stoppers positioned therebetween, and thus the number of vertical stoppers in the multiple terrace structure may be reduced, and the multiple terrace structure may be simplified.

According to the configuration of the present embodiment, heights of optical modes of the flip-chip bonded light source element and the ECs 120a and 120b may be aligned to effectively perform an optical alignment (c1, c2), thereby allowing output light of the light source element to be effectively transmitted to another optical element through silicon optical WGs of the ECs 120a and 120b. Each of the ECs 120a and 120b may include an SSC for effective optical coupling. A thickness of the SSC of each of the ECs 120a and 120b may be about 6 μm.

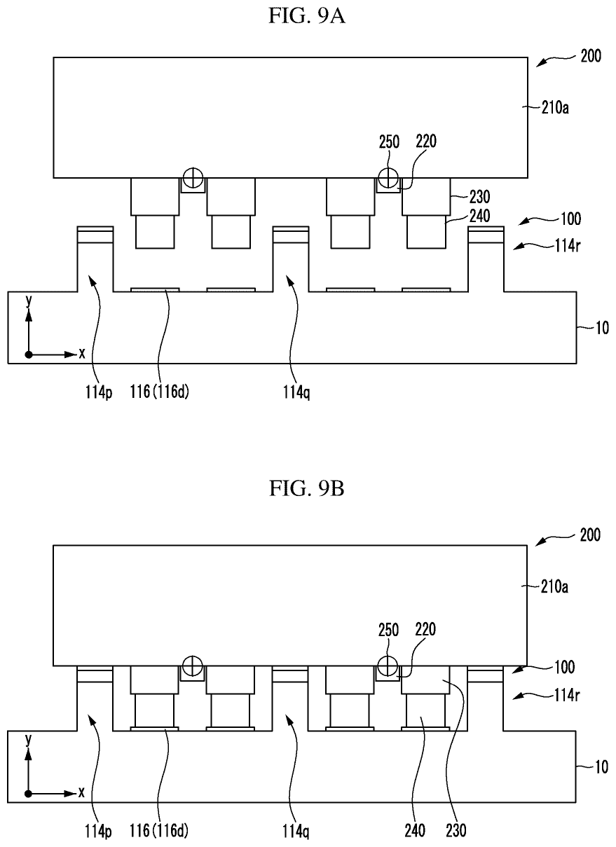

FIGS. 9A and 9B are exemplary diagrams for describing a process for manufacturing a multiple-light-source integration structure of a silicon photonics chip having the multiple terrace structure of FIG. 8.

First, referring to FIG. 9A, a silicon photonics chip 100 and a light source element 200 may be prepared. The light source element 200 may be prepared to have a plurality of light sources 250 having a different wavelength for flip-chip bonding to the silicon photonics chip 100. In the present embodiment, the light sources 250 may include a first light source of a first wavelength and a second light source of a second wavelength. Each light source may be expressed as an optical mode (LD optical mode) of an activated LD or its state.

The silicon photonics chip 100 may include a silicon substrate 10, a plurality of vertical stoppers 114p, 114q, 114r, etc., and one pair of first UBM layers 116 and 116d each arranged between adjacent vertical stoppers. The silicon photonics chip 100 may include at least two terrace structures. Here, a first group of vertical stoppers may be arranged on a first terrace, and a second group of vertical stoppers may be arranged on a second terrace. In this case, the first group of vertical stoppers and the second group of vertical stoppers may include a plurality of stoppers 114q and the like that are shared by both groups and used in common.

The light source element 200 may include a die 210a, a WG layer 220, an electrode 230, and a light source 250. The light source element 200 may be referred to as a 2P-LD having two LDs 250.

When the light source element 200 is flip-chip bonded onto the silicon photonics chip 100, solder bumps for flip-chip bonding are not formed on the silicon photonics chip 100, but solder bumps 240 for flip-chip bonding are formed on the light source element 200. The solder bumps 240 may be formed on the electrode 230 of the light source element 200.

Next, referring to FIG. 9B, the light source element 200 having the solder bumps formed on its surface may be flip-chip bonded onto the multiple terrace structure.

According to the configuration of the present embodiment, the light source element equipped with light sources of the different wavelength may be effectively flip-chip bonded onto the multiple terrace structure, which is a trench structure formed on a single substrate.

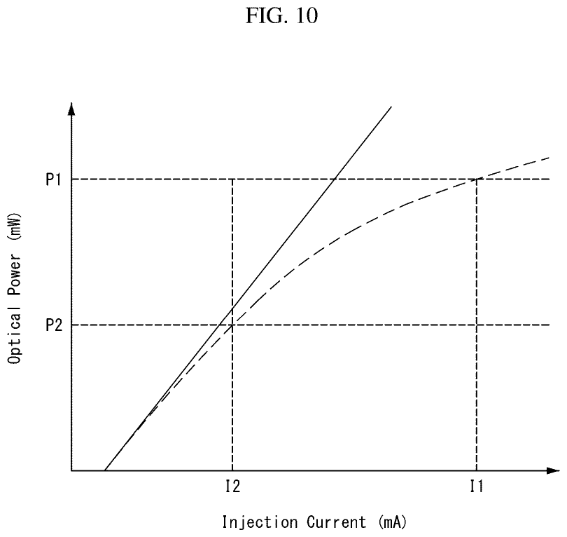

FIG. 10 is a graph showing a relationship between injection current and optical power for a silicon photonics chip with a light source element integrated on the multiple terrace structure of FIG. 8.

Referring to FIG. 10, a comparative example (see a dotted line) is a graph showing optical power according to injection current of a LD. In the comparative example, as the injection current increases, the optical power does not increase linearly due to a thermal running effect, but rather the increase rate decreases and gradually increases. That is, even when a first current I1 is applied, the optical power is saturated, and the light is output with first optical power P1. In addition, when the first current I1 is applied, the heat of the LD increases rapidly, and a problem of reduced luminous efficiency occurs.

In order to solve the above problem, in the present embodiment (see a solid line), a 2P-LD is used as a light source of a silicon photonics chip. When a 2P-LD is used, two pieces of second optical power P2 corresponding to half of the first optical power P1 may be output with a second current I2 corresponding to approximately half of the first current I1. That is, the injection current I2 injected into the two light sources is sufficiently low compared to the first current I1, and thus it is energy efficient.

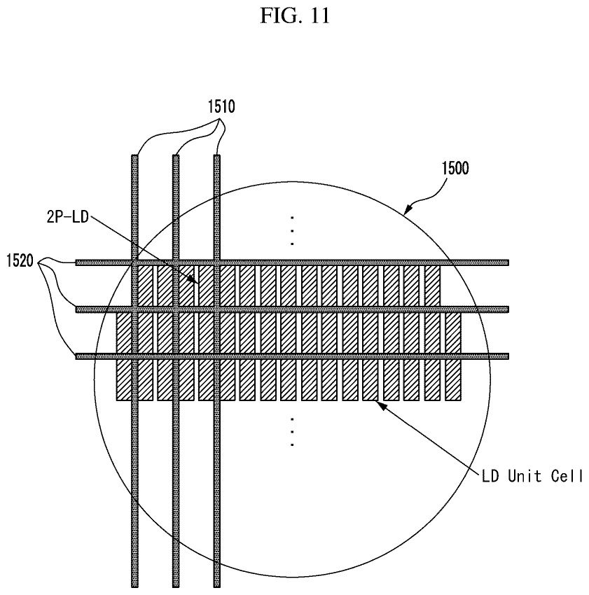

FIG. 11 is an exemplary diagram for describing a light source element that can be employed in the multiple-light-source integration structure of the silicon photonics chip of the present embodiment.

As illustrated in FIG. 11, a light source element includes a 2P-LD. The 2P-LD may be implemented by dicing two LD unit cells by blades 1510 and 1520 on a wafer 1500 in which LDs are formed as unit cells.

LDs of CWDM wavelengths are usually manufactured with separate wafers for each wavelength. That is, a light source of a L1 wavelength is manufactured in a first wafer, and a light source of a L2 wavelength is manufactured in a second wafer, which is different from the first wafer. In this case, since the 2P-LD of the present embodiment is implemented by dicing two unit cells on one wafer, two outputs of the 2P-LD may have the same wavelength.

Naturally, when the light source of the L1 wavelength and the light source of the L2 wavelength are alternately formed on a single wafer, the 2P-LD of the present embodiment may be implemented by dicing two unit cells on one wafer, and in this case, outputs of the 2P-LD may have the L1 wavelength and the L2 wavelength.

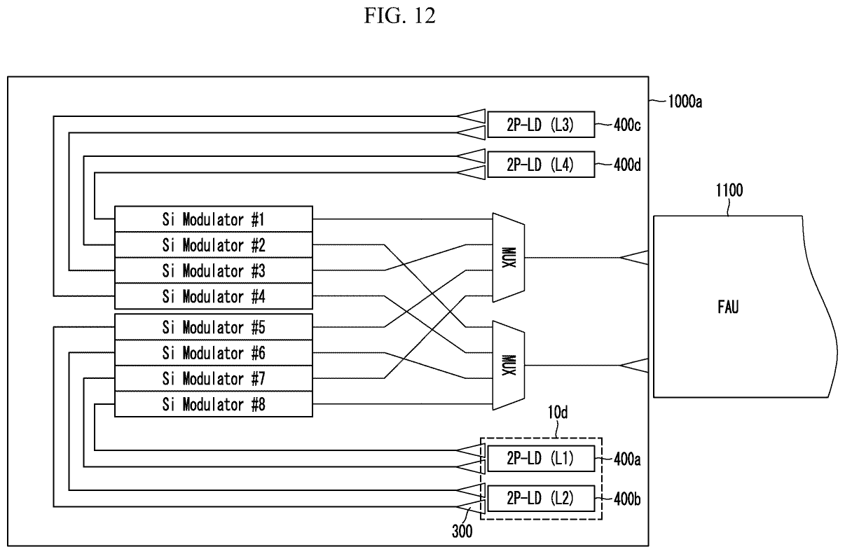

FIG. 12 is a schematic plan view for describing a silicon photonics-based optical transmitter to which a multiple-light-source integration structure according to still another embodiment of the present disclosure is employed.

Referring to FIG. 12, a multiple-light-source integration structure of a silicon photonics chip may be configured by flip-chip bonding each die 10d, on which two light sources 400a and 400 or 400c and 400d for CWDM optical transmission are mounted, onto the multiple terrace structure of the silicon photonics chip. That is, the silicon photonics chip may have a structure in which two chips, each of which has two 2P-LDs mounted on one die 10d, are flip-chip bonded. In such a silicon photonics-based optical transceiver, the silicon photonics chip may be referred to as a silicon photonics 2×CWDM optical transmission chip.

The output of each 2P-LD of the silicon photonics chip, onto which the two 2P-LDs 400a and 400 or 400c and 400d are flip-chip bonded, is coupled to a silicon optical WG through an EC 300, which is an optical coupling element. In addition, the output may be modulated through a silicon optical modulator (Si modulator), then wavelength-multiplexed in an optical multiplexer (MUX), and output to a FAU 1100.

The multiple-light-source integration structure of the silicon photonics chip having the multiple terrace structure of the present embodiment is formed by forming solder bumps on each of a plurality of light sources and independently flip-chip bonding the plurality of light sources onto the multiple terrace structure. That is, in manufacturing the silicon photonics-based optical transmitter of the present embodiment, the solder bumps are formed on the light sources without forming solder bumps on the UBM layer of the multiple terrace structure to perform flip-chip bonding, and through such a configuration, optical alignment errors occurring in existing flip-chip bonding of a plurality of light sources may be eliminated or reliably reduced.

Further, according to the configuration of the present embodiment, light sources requiring high output optical power may be effectively provided due to an insertion loss of a silicon light source in a silicon PIC.

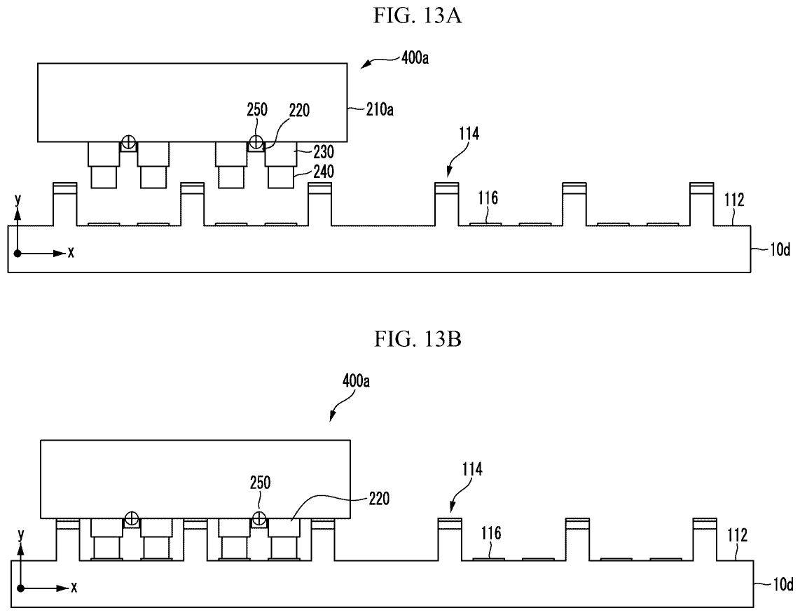

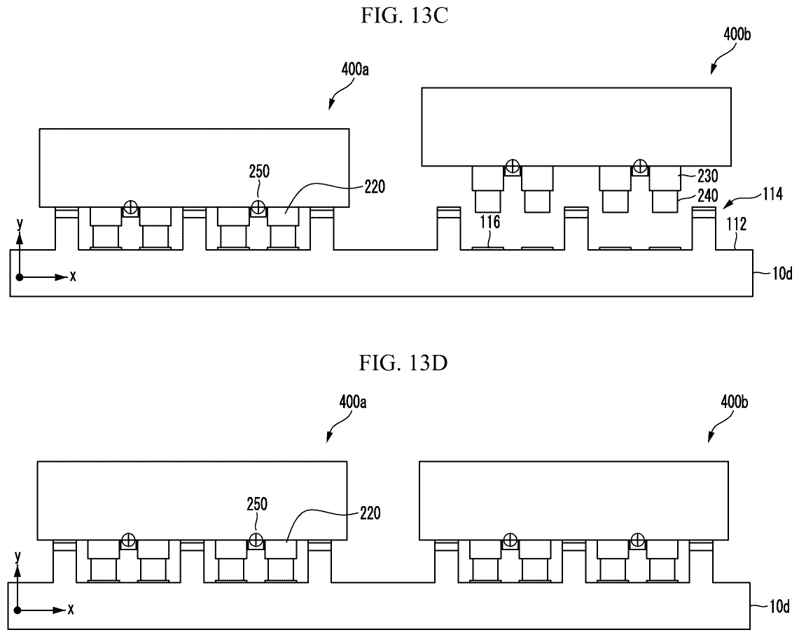

FIGS. 13A to 13D are exemplary diagrams for describing a flip-chip bonding process that can be employed in the multiple-light-source integration structure of the silicon photonics chip of FIG. 12.

FIGS. 13A to 13D illustrate in more detail a case of flip-chip bonding of a plurality of 2P-LDs onto the multiple terrace structure of the silicon photonics chip of the present embodiment.

First, as illustrated in FIGS. 13A and 13B, a first light source element 400a equipped with a 2P-LD of a L1 wavelength is flip-chip bonded onto the multiple terrace structure of the silicon photonics chip. In this case, in the multiple terrace structure, there are no solder bumps, and only a UBM layer 116 is formed. Solder bumps 240 are formed on the electrode 230 of the first light source element 400a.

Next, as illustrated in FIGS. 13C and 13D, a second light source element 400b equipped with a 2P-LD of a L2 wavelength is flip-chip bonded onto the multiple terrace structure of the silicon photonics chip. In this case, in the multiple terrace structure, there are no solder bumps and only a UBM layer 116 is formed. Solder bumps 240 are formed on the electrode 230 of the second light source element 400b.

According to the present embodiment, the terrace structure and the UBM layer are formed on the silicon chip, but the solder bumps are formed on the light source element that is flip-chip bonded. For such characteristics, a silicon element layer formed on a lower oxide layer as a stopper for aligning a height of an optical mode of the light source element and a height of an optical mode of the silicon photonics chip may be utilized.

Meanwhile, when a silicon oxide (SiO₂) BOX layer or a silicon substrate layer corresponding to the lower oxide layer is used as a stopper, there is a problem in that it is difficult to implement an accurate height because there is no boundary when an upper oxide layer is removed, and it is also difficult to implement an accurate height at a height below thereto, which increases time and cost. In addition, since solder bumps are formed on UBM layers of the silicon photonics chip, independent flip-chip bonding is made difficult when attempting to integrate a plurality of light sources. That is, when multiple light source elements are sequentially flip-chip bonded, the solder bumps that have been previously flip-chip bonded may melt when the solder bumps are flip-chip bonded subsequently, causing a serious problem of optical alignment to be broken. Therefore, in the present embodiment, in order to integrate the multiple light sources into the silicon photonics chip, the multiple terrace structure of the silicon photonics chip is first prepared, and the flip-chip bonding process is performed using the light source having the solder bumps.

According to the present embodiment, a plurality of chips on which at least one light source is mounted may be independently flip-chip bonded to obtain very precise optical alignment. In addition, a method of flip-chip bonding a light source element having two outputs to supply energy-efficient optical power may be provided.

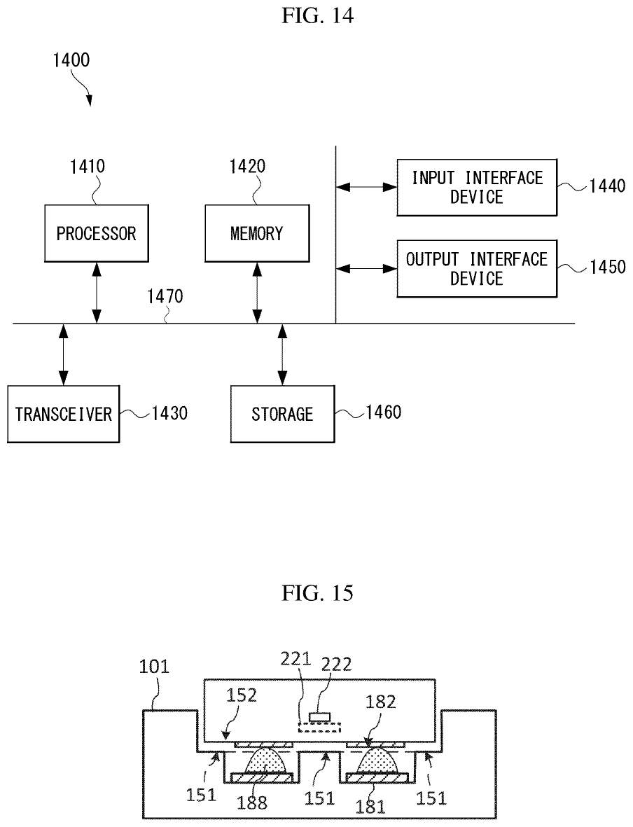

FIG. 14 is a schematic plan view of a control device of semiconductor equipment that performs a method of manufacturing a silicon photonics chip according to the present embodiment.

Referring to FIG. 14, a control device 1400 may control an operation of semiconductor equipment. The semiconductor equipment may include etching equipment that forms a terrace structure by etching one surface of a silicon substrate, equipment that flip-chip bonds a light source element onto the terrace structure of the silicon substrate, etc. Examples of the equipment for flip-chip bonding may include equipment for a UBM layer formation process on a wafer, a bump formation process on a light source element, a flip-chip bonding process, and an underfill and curing process.

Further, the control device 1400 may include at least one processor 1410 as a type of computing device. The processor 1410 may execute a program or instructions stored in a memory 1420 or storage device 1460. The processor 1410 may be a central processing unit (CPU), a graphics processing unit (GPU), or a dedicated processor on which the methods according to the embodiments of the present disclosure are performed. The memory 1420 or the storage device 1460 may be configured as at least one of a volatile storage medium and a non-volatile storage medium. For example, the memory 1420 may be configured as at least one of a read-only memory (ROM) and a random-access memory (RAM).

Further, as a type of a communication terminal or a node connected to a network, the control device 1400 may further include a transmission and reception device 1430 for transmitting or receiving signals and data to or from other nodes through a wired or wireless network. In addition, the control device 1400 may include an input interface device 1440 or output interface device 1450 for communication with the outside. The control device 1400, the memory 1420, the transmission and reception device 1430, the input interface device 1440, the output interface device 1450, and the storage device 1460 may be connected to each other by a bus 1470 or dedicated interface.

Meanwhile, in the embodiments of the present disclosure, in order to clearly describe the technical features of the present disclosure, solder bumps are described as being formed only on light source elements and not being formed at all on the UBM layer in a flip-chip process, but the present disclosure is not limited to such a configuration, and it should be clear that it may be included that auxiliary solder bumps or dummy solder bumps of a smaller size or a smaller amount than the solder bumps formed on the light source element may be formed in the flip-chip process.

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A method of manufacturing a silicon photonics chip, comprising:
forming a terrace structure on one surface of a substrate, wherein the terrace structure has a bottom surface of a trench structure formed on the one surface and a plurality of vertical stoppers in a form of a pedestal that protrude integrally with the substrate from the bottom surface, and each of the plurality of vertical stoppers includes a body, an oxide layer formed on an upper surface of the body, and a waveguide layer formed on the oxide layer;
forming an under bump metallization (UBM) layer on the bottom surface;
forming solder bumps on a light source element; and
performing flip-chip bonding of the light source element on which the solder bumps are formed onto the terrace structure so that the solder bumps comes into contact with the UBM layer.

2. The method of claim 1, wherein, in the forming of the solder bumps, the solder bumps are formed on an electrode of the light source element.

3. The method of claim 2, wherein the electrode has a metal layer of a form of multilayers including a bonding layer, a diffusion barrier layer, and a wetting layer.

4. The method of claim 1, wherein the forming of the solder bumps includes:
forming first solder bumps on a first light source element to be flip-chip bonded onto a first terrace structure including a first group of vertical stoppers among the plurality of vertical stoppers; and
forming second solder bumps on a second light source element to be flip-chip bonded onto a second terrace structure including a second group of vertical stoppers among the plurality of vertical stoppers.

5. The method of claim 4, wherein the performing of the flip-chip bonding includes performing flip-chip bonding of the first light source element onto the first terrace structure so that the first solder bumps connect an electrode of the first light source element to a first UBM layer.

6. The method of claim 5, wherein the performing of the flip-chip bonding further includes, after the performing of the flip-chip bonding of the first light source element, performing flip-chip bonding of the second light source element onto the second terrace structure so that the second solder bumps connect an electrode of the second light source element to a second UBM layer.

7. The method of claim 6, wherein at least one of the first light source element and the second light source element includes a 2-port laser diode.

8. The method of claim 4, wherein the first group of vertical stoppers and the second group of vertical stoppers include shared vertical stoppers that are used by both of the first light source element and the second light source element when the flip-chip bonding is performed.

9. The method of claim 1, further comprising filling a gap between the terrace structure and the light source element and filling a gap between the solder bumps with an underfill material.

10. The method of claim 1, further comprising forming at least one edge coupler on the one surface of the substrate through a semiconductor process.

11. A silicon photonics chip comprising:
a terrace structure formed on one surface of a substrate in a form of a trench, wherein the terrace structure has a bottom surface formed with a step lowered on the one surface, and a plurality of vertical stoppers in a form of a pedestal that protrude integrally with the substrate from the bottom surface and each of the plurality of vertical stoppers includes a pedestal-shaped body, an oxide layer formed on an upper surface of the body, and a waveguide layer formed on the oxide layer;
an under bump metallization (UBM) layer formed on the bottom surface;
a light source element flip-chip bonded onto the terrace structure; and
solder bumps formed to connect the electrode to the UBM layer through the flip-chip bonding in a state of being formed on the electrode of the light source element in advance.

12. The silicon photonics chip of claim 11, wherein the electrode has a form of a multilayer metal layer including a bonding layer, a diffusion barrier layer, and a wetting layer.

13. The silicon photonics chip of claim 12, wherein the UBM layer is a single-layer or multi-layer metal layer containing one material or a combination of two or more materials selected from among silver, copper, gold, chromium, aluminum, tungsten, zinc, brass, nickel, iron, bronze, platinum, and tin.

14. The silicon photonics chip of claim 11, wherein the light source element includes a first light source element flip-chip bonded onto a first terrace structure formed in a first area of the bottom surface, and a second light source element flip-chip bonded onto a second terrace structure formed in a second area of the bottom surface.

15. The silicon photonics chip of claim 14, wherein the solder bumps include first solder bumps formed on an electrode of the first light source element that is flip-chip bonded onto the first terrace structure and second solder bumps formed on an electrode of the second light source element that is flip-chip bonded onto the second terrace structure.

16. The silicon photonics chip of claim 14, wherein each of the first light source element and the second light source element is a 2-port light source element including two light sources.

17. The silicon photonics chip of claim 14, wherein each of the first light source element and the second light source element has two 2-port light source elements each including two light sources.

18. The silicon photonics chip of claim 14, wherein vertical stoppers positioned in the first area and vertical stoppers positioned in the second area include shared vertical stoppers used by both of the first light source element and the second light source element.

19. The silicon photonics chip of claim 11, further comprising an underfill material with which a gap between the terrace structure and the light source element and a gap between the solder bumps are filled.

20. The silicon photonics chip of claim 11, further comprising at least one edge coupler formed on the one surface of the substrate.
